(19) United States
(12) Patent Application Publication
(10) Pub. No.: US 2014/0308758 A1
(43) Pub. Date: Oct. 16, 2014

(54) PATTERNING MAGNETIC MEMORY

(71) Applicant: Applied Materials, Inc., Santa Clara, CA (US)

(72) Inventors: Srinivas D. Nemani, Sunnyvale, CA (US); Sumit Agarwal, San Jose, CA (US); Jeremiah T. Pender, San Jose, CA (US); Jonathan Germain, San Francisco, CA (US); Khoi Doan, San Jose, CA (US); Bradley Howard, Pleasanton, CA (US)

(21) Appl. No.: 13/934,017

(22) Filed: Jul. 2, 2013

Related U.S. Application Data
(60) Provisional application No. 61/810,636, filed on Apr. 10, 2013.

(51) Int. Cl. H01L 43/12

(52) U.S. Cl. CPC H01L 43/12
USPC 438/3

(57) ABSTRACT

Methods of forming material junctions for magnetic memory devices are described. The methods involve providing a material stack including a bottom magnetic tunneling junction layer, a tunneling barrier layer, and a top magnetic tunneling junction layer (from bottom to top) on a substrate. The top magnetic tunneling junction layer is patterned to form a top magnetic tunneling junction and then a dielectric spacer layer may be formed over the top magnetic tunneling junction. The dielectric spacer is etched to leave a vertical dielectric spacer to maintain electrical separation between the top magnetic tunneling junction and the bottom magnetic tunneling junction during and following subsequent etching/processing. In an alternative embodiment the spacer layer is lithographically defined.

### CROSS-REFERENCES TO RELATED APPLICATIONS

This application claims the benefit of U.S. Prov. Pat. App. No. 61/810,636 filed Apr. 10, 2013, and titled “PATTERNING MAGNETIC MEMORY,” which is hereby incorporated herein in its entirety by reference for all purposes.

### STATEMENT AS TO RIGHTS TO INVENTIONS MADE UNDER FEDERALLY SPONSORED RESEARCH AND DEVELOPMENT

NOT APPLICABLE

### REFERENCE TO A “SEQUENCE LISTING,” A TABLE, OR A COMPUTER PROGRAM LISTING APPENDIX SUBMITTED ON A COMPACT DISK

NOT APPLICABLE

### BACKGROUND OF THE INVENTION

Memory devices are typically provided as internal, semiconductor, integrated circuits in computers or other electronic devices. There are many different types of memory, including random-access memory (RAM), read only memory (ROM), dynamic random access memory (DRAM), synchronous dynamic random access memory (SDRAM), flash memory, resistance variable memory, such as phase change random access memory (PCRAM) and resistive random access memory (RRAM), and magnetic random access memory (MRAM), such as spin torque transfer random access memory (STT RAM), among others.

MRAM devices can employ a magnetic tunneling junction (MTJ) that can be viewed as a multi-state resistor due to different relative orientations (e.g., parallel and antiparallel) of the magnetic moments, which can change the magnitude of a current passing through the device. In a write process, magnetic fields caused by currents passing through conductive lines (e.g., word and bit lines) can be used to switch a magnetic moment direction of a “free” material of the MTJ, which can place the device in a high or low resistance state. A read process can then be used to determine the state of cell.

As the size of MRAM cells decreases, the widths of magnetic tunneling junctions and barriers decrease, which increases manufacturers' reliance on the homogeneity of the materials which make up these functional regions. New process flows are necessary to maintain the integrity of functional magnetic regions across the widths of these devices.

### BRIEF SUMMARY OF THE INVENTION

Methods of forming material junctions for magnetic memory devices are described. The methods involve providing a material stack including a bottom magnetic tunneling junction layer, a tunneling barrier layer, and a top magnetic tunneling junction layer (from bottom to top) on a substrate. The top magnetic tunneling junction layer is patterned to form a top magnetic tunneling junction and then a dielectric spacer layer may be formed over the top magnetic tunneling junction. The dielectric spacer is etched to leave a vertical dielectric spacer to maintain electrical separation between the top magnetic tunneling junction and the bottom magnetic tunneling junction during and following subsequent etching/processing. In an alternative embodiment the spacer layer is lithographically defined.

Embodiments of the invention include methods of forming a magnetic memory junction on a substrate. The methods include the sequential steps: (i) providing a stack of material layers on the substrate in the following order from top to bottom: top magnetic tunneling junction layer/tunneling barrier layer/bottom magnetic tunneling junction layer/substrate, (ii) patterning the top magnetic tunneling junction layer, using lithography, to form a top magnetic tunneling junction, (iii) forming a vertical dielectric flank extending along the side of the top magnetic tunneling junction, and (iv) etching the bottom magnetic tunneling junction layer to form a bottom magnetic tunneling junction.

Additional embodiments and features are set forth in part in the description that follows, and in part will become apparent to those skilled in the art upon examination of the specification or may be learned by the practice of the disclosed embodiments. The features and advantages of the disclosed embodiments may be realized and attained by means of the instrumentalities, combinations, and methods described in the specification.

### BRIEF DESCRIPTION OF THE DRAWINGS

A further understanding of the nature and advantages of the disclosed embodiments may be realized by reference to the remaining portions of the specification and the drawings.

FIGS. 1A-1E are cross-sectional diagrams of a magnetic memory patterning process according to disclosed embodiments.

FIG. 2 is a flow chart of a magnetic memory patterning process according to disclosed embodiments.

In the appended figures, similar components and/or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

### DETAILED DESCRIPTION OF THE INVENTION

Methods of forming material junctions for magnetic memory devices are described. The methods involve providing a material stack including a bottom magnetic tunneling junction layer, a tunneling barrier layer, and a top magnetic tunneling junction layer (from bottom to top) on a substrate. The top magnetic tunneling junction layer is patterned to form a top magnetic tunneling junction and then a dielectric spacer layer may be formed over the top magnetic tunneling junction. The dielectric spacer is etched to leave a vertical dielectric spacer to maintain electrical separation between the top magnetic tunneling junction and the bottom magnetic tunneling junction during and following subsequent etching/processing. In an alternative embodiment the spacer layer is lithographically defined.

The inventors have found new ways to protect magnetic material from processing damage which may otherwise occur. The benefits garnered by taking the preventative steps disclosed herein include prevention of electrically shorting the top magnetic tunneling junction to the bottom magnetic tunneling junction and also include prevention of oxidation or other damage to the top magnetic tunneling junction itself. These benefits make magnetic memory cells able to retain information with greater resilience. In some embodiments, the tunneling barrier is partially or fully protected as well.

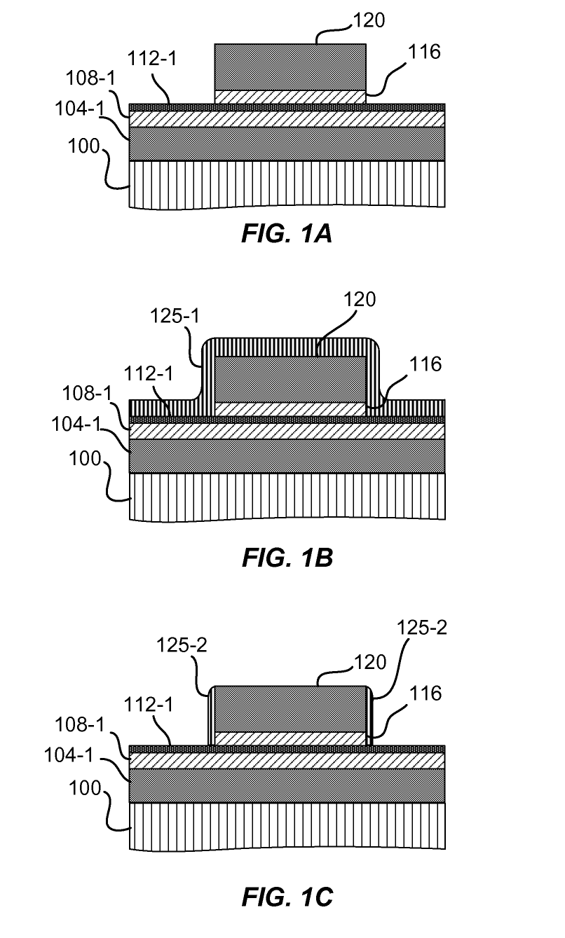

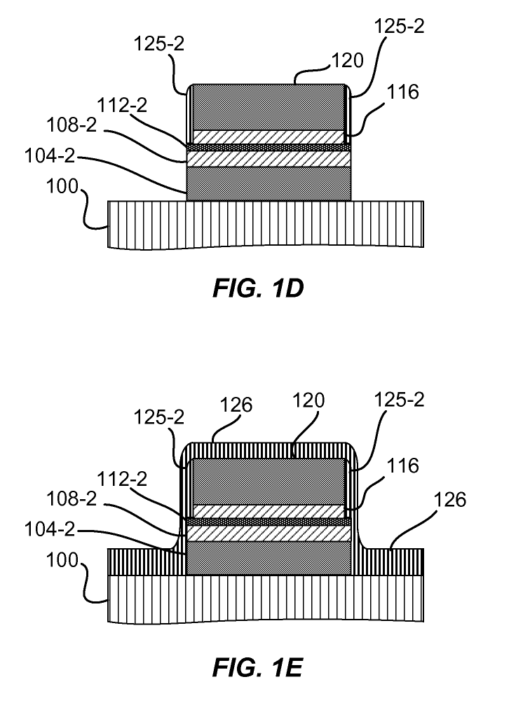

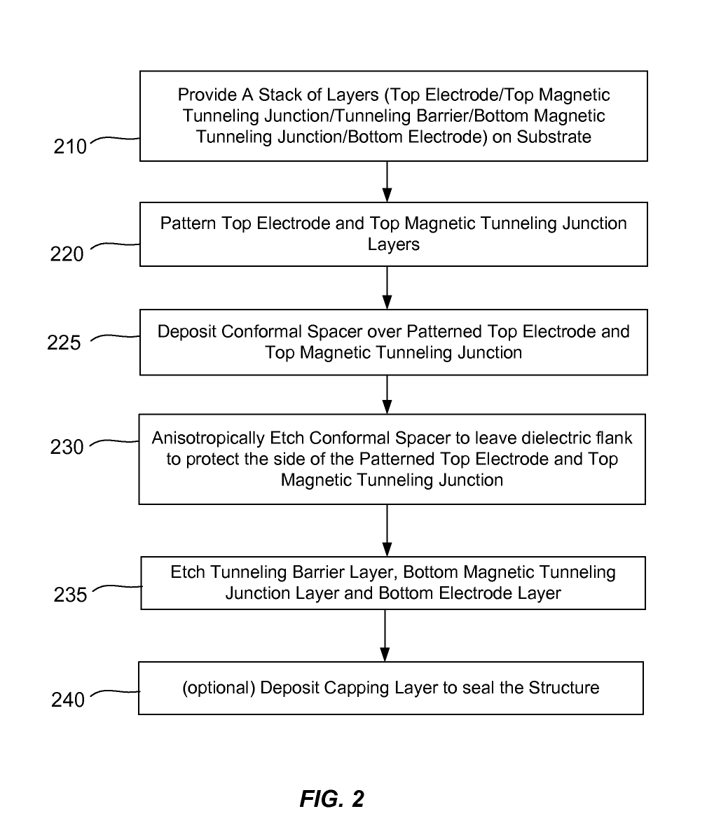

In order to better understand and appreciate the invention, reference is now made to FIGS. 1A-1E which are cross-sectional diagrams of a magnetic memory patterning process according to disclosed embodiments. Reference will concurrently be made to FIG. 2, which is a flow chart of a magnetic memory patterning process according to embodiments of the invention. Layers of material are deposited prior to the steps shown in the figure, in order to provide a stack of layers to produce a magnetic memory junction. The stack of layers may include, from top to bottom, layers of top electrode layer (not shown in FIG. 1)/top magnetic tunneling junction layer (not shown in FIG. 1)/tunneling barrier layer(112)/bottom magnetic tunneling junction layer(108)/bottom electrode layer(104)/substrate(100). The substrate may also be referred to etch stop layer (100) to represent the function layer 100 serves in the second-to-last step of FIG. 2. This stack of layers is provided on the substrate in step 210. The top two layers are then patterned (step 220) to form top electrode 120 and top magnetic tunneling junction layer 116. Following this step, tunneling barrier layer 112, bottom magnetic tunneling junction layer 108 and bottom electrode layer 104 remain unpatterned. Deviations from this particular example are also within the scope of the invention and will be outlined shortly.

A dielectric spacer layer 125-1 is then deposited (step 225) over the top electrode 120 and the top magnetic tunneling junction 116. Dielectric spacer layer 125-1 is then etched (step 230) to form vertical dielectric flank 125-2 on the side of each of top electrode 120 and top magnetic tunneling junction 116. The etch leaves vertical dielectric flank 125-2 on the side of each of top electrode 120 and top magnetic tunneling junction 116. Vertical dielectric flank 125-2 extends upward to the top of top magnetic tunneling junction 116, beyond the top of top magnetic tunneling junction 116 or to the top of top electrode 125-2, in disclosed embodiments. Vertical dielectric flank 125-2 extends to the top of tunneling barrier 112 (and beyond in some cases). The importance of having flanks 125-2 extend at least to the bottom of top magnetic barrier 116 lies, in part, in the ability of vertical dielectric flank 125-2 to prevent or discourage the device from developing electrical shorts during subsequent processing. Following formation of vertical dielectric flank 125-2, each of tunneling barrier layer 112-1, bottom magnetic tunneling junction layer 108-1 and bottom electrode layer 104-1 are etched (step 235) to form tunneling barrier 112-2, bottom magnetic tunneling junction 108-2 and bottom electrode 104-2, respectively. Etching multiple layers may be performed in a single etch or in multiple steps, for example, by performing a customized etch process for each separate layer. The structure formed by steps 210-235 may then be sealed (in step 240) by depositing a dielectric capping layer 126 to complete the processing sequence.

Dielectric spacer layer 125-1 may be a conformal dielectric spacer layer and the etch step (230) may then be an anisotropic etch in the vertical direction to form the vertical dielectric flank 125-2. A vertical anisotropic etch of a dielectric spacer layer may sometimes be referred to as a controlled spacer etch. Alternatively, dielectric spacer layer 125-1 may be deposited such that the sidewall deposition proceeds more rapidly. The dielectric spacer layer 125-1 would then be thicker on the side of top magnetic tunneling junction 116 and top electrode 120 than dielectric spacer layer 125-1 would be on the top of top electrode 120. In this alternative example, the etch step may not necessarily be anisotropic in the vertical direction. The alternative etch step may actually be an isotropic etch in disclosed embodiments of the invention.

Step 220 may involve etching into (but not all the way) or all the way through the tunneling barrier layer, in embodiments of the invention. In the first case, the vertical dielectric flank extends below the bottom of the top magnetic tunneling junction to provide protection to a portion of the tunneling barrier in addition to the top magnetic tunneling junction. In the second case, the vertical dielectric flank extends to (or past) the bottom of the tunneling barrier to provide protection for both the tunneling barrier and the top magnetic tunneling junction. Put another way, step 220 may involve etching through the tunneling barrier layer to form a tunneling barrier sandwiched between the top magnetic tunneling junction and the bottom magnetic tunneling barrier layer.

Sealing the completed structure (step 240) is optional but would involve forming a capping layer over the top electrode, the vertical dielectric flank, the bottom magnetic tunneling junction, the bottom electrode and the substrate. The capping layer may not make direct contact with the sides of the top magnetic tunneling junction in disclosed embodiments.

Geometrically, a vertical dielectric flank may actually form a continuous shape as viewed from above. As a result, vertical dielectric flank 125-2 (shown in cross section in FIGS. 1C-1E) appears to be two separate vertical dielectric flanks The apparently separate vertical dielectric flanks 125-2 may be portions of a continuous loop of material, in disclosed embodiments. Viewed from above, vertical dielectric flank 125-2 may appear circular, ellipsoidal or a variety of other simple shapes.

By including vertical dielectric flank 125-2, electrical bridging between top magnetic tunneling junction 116 and bottom magnetic tunneling junction 108-2 has been prevented or reduced. Electrical bridging involves making an undesirable electrical connection between two points, which compromises the function of the completed integrated circuit. Prior art methods of coping with this electrical bridging has been to expose the stack of material to an oxygen (O₂)-containing plasma after the prior art equivalent of step 235. In doing so, any flakes of metal which were electrically bridging between a top magnetic tunneling junction and a bottom magnetic tunneling junction may be oxidized and thus converted to non-conductive (dielectric) material. Inclusion of the two dielectric flanks 125-2 therefore provides an additional benefit by protecting top electrode 120, top magnetic tunneling junction 116 and (optionally) tunneling barrier 112-2 from any processing which may be conducted after formation of the flanks Such downstream processing may include plasma treatments (either chemically reactive or non-reactive), ion-implantation or other processes which may alter any of these materials. The vertical dielectric flank 125-2, for example, may protect magnetic junction stacks from otherwise deleterious effects such as, as examples, a loss of grain size or grain size registration between top and bottom magnetic tunneling junctions (116, 108-2) or a loss of barrier capability of tunneling barrier 112-2.

Patterning the top electrode layer and the top magnetic tunneling junction layer (step 220) may be performed in one step or two (or more) distinct steps, in embodiments, to increase the overall etch rate by tailoring each etch to remove the material under etch. Similarly, etching the bottom magnetic tunneling junction layer and the bottom electrode layer in step 235 may be performed in one or two (or more) distinct steps, in disclosed embodiments. In order to facilitate patterning the top electrode layer, the top electrode may further include a conductive hard mask. The top electrode may then include a hard mask which is patterned and subsequently used to pattern an electrode from the top electrode layer. For the purposes of the claims described herein, the hard mask material and the patterned metal collectively form top electrode 120, since the conductive hard mask material is left into the device. In case some or all the hard mask is removed, only the remaining portion (if present) would be considered part of top electrode 120. In disclosed embodiments, top magnetic tunneling junction layer and top magnetic tunneling junction include the top electrode layer and top electrode, respectively. Similarly, bottom magnetic tunneling junction layer and bottom magnetic tunneling junction may include, in embodiments, the bottom electrode layer and bottom electrode, respectively.

The processing sequences described and claimed herein apply to various combinations of materials. For example, dielectric spacer layers and the vertical dielectric flank may be silicon nitride or silicon oxide as well as a variety of other dielectric materials. Top electrode layers, top electrodes and even conductive hard masks may be tantalum, tungsten and a variety of other conductors. Tunneling barrier layers and tunneling barriers may be made from, for example, typically oxide layers such as magnesium oxide or aluminum oxide, but many other material options exist. Magnetic tunneling junction layers and magnetic tunneling junctions may be made from iron cobalt and cobalt iron boron and the like. Bottom electrode layers and bottom electrodes may be made from tantalum, tungsten, platinum, platinum manganese, palladium cobalt and a variety of other conducting materials. The etch stop layer (aka substrate in this case) may be made from a combination of tantalum and ruthenium, but a broad range of materials may be used, including silicon oxide.

Lithography may be used as an alternative method of forming the vertical dielectric flank. In this case, the steps of depositing the dielectric spacer (225) and etching the dielectric spacer (230) would be supplanted by a more costly but still manufacturable option based on, for example, photolithography, e-beam lithography or similar process. Steps 225 and 230 may be replaced by the sequential steps: forming a spacer layer over the top electrode and the top magnetic tunneling junction, and patterning the spacer layer, using lithography, to form the vertical dielectric flank.

Magnetic memory cells are typically defined as holding a “1” when both the top magnetic tunneling junction and the bottom magnetic tunneling junction are magnetized in the same direction and storing a “0” when the magnetizations are not in the same direction. Also typically, one of the junctions is “pinned” in a specific direction and the other is “unpinned” and can change magnetic polarization to either store a “1” or a “0”. In embodiments of the invention, the bottom magnetic tunneling junction is pinned and the top magnetic tunneling junction is unpinned. Alternatively, the top magnetic tunneling junction may be pinned and the bottom magnetic tunneling junction is unpinned, in disclosed embodiments. Some forms of MRAM use more magnetic tunneling junction layers than described here, in which case they may all be electrically isolated from one another using analogously extended techniques according to the descriptions described herein.

In the preceding description, for the purposes of explanation, numerous details have been set forth in order to provide an understanding of various embodiments of the present invention. It will be apparent to one skilled in the art, however, that certain embodiments may be practiced without some of these details, or with additional details.

As used herein “substrate” may be a support substrate with or without layers formed thereon. The top layer of the substrate may be an insulator, a conductor or a semiconductor of a variety of doping concentrations and profiles and may, for example, be a semiconductor substrate of the type used in the manufacture of integrated circuits. “Tungsten” as used herein is predominantly W but may include minority concentrations of other elemental constituents such as nitrogen, oxygen, hydrogen, carbon and the like. Of course, “tungsten” may consist of only tungsten. “Silicon nitride” of the capping layer and vertical dielectric flank may be Si₃N₄ but may include significant concentrations of other elemental constituents. “Silicon oxide” is predominantly SiO₂ but may include minority concentrations of other elemental constituents such as nitrogen, hydrogen, carbon and the like. In some embodiments, silicon oxide material consists of silicon and oxygen. “Tantalum” is predominantly tantalum but may include minority concentrations of other elemental constituents such as oxygen, nitrogen, hydrogen, carbon and the like. Tantalum may consist only of tantalum in some embodiments. The other materials described herein are referred to with analogous definitions.

As used herein, a conformal layer refers to a generally uniform layer of material on a surface in the same shape as the surface, i.e., the surface of the layer and the surface being covered are generally parallel. A person having ordinary skill in the art will recognize that the deposited material likely cannot be 100% conformal and thus the term “generally” allows for acceptable tolerances.

Having disclosed several embodiments, it will be recognized by those of skill in the art that various modifications, alternative constructions, and equivalents may be used without departing from the spirit of the disclosed embodiments. Additionally, a number of well known processes and elements have not been described in order to avoid unnecessarily obscuring the present invention. Accordingly, the above description should not be taken as limiting the scope of the invention.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed. The upper and lower limits of these smaller ranges may independently be included or excluded in the range, and each range where either, neither or both limits are included in the smaller ranges is also encompassed within the invention, subject to any specifically excluded limit in the stated range. Where the stated range includes one or both of the limits, ranges excluding either or both of those included limits are also included.

As used herein and in the appended claims, the singular forms “a”, “an”, and “the” include plural referents unless the context clearly dictates otherwise. Thus, for example, reference to “a process” includes a plurality of such processes and reference to “the dielectric material” includes reference to one or more dielectric materials and equivalents thereof known to those skilled in the art, and so forth.

Also, the words “comprise,” “comprising,” “include,” “including,” and “includes” when used in this specification and in the following claims are intended to specify the presence of stated features, integers, components, or steps, but they do not preclude the presence or addition of one or more other features, integers, components, steps, acts, or groups.

What is claimed is:

1. A method of forming a magnetic memory junction on a substrate, the method comprising the sequential steps:
(i) providing a stack of material layers on the substrate in the following order from top to bottom: top magnetic tunneling junction layer/tunneling barrier layer/bottom magnetic tunneling junction layer/substrate,
(ii) patterning the top magnetic tunneling junction layer, using lithography, to form a top magnetic tunneling junction,
(iii) forming a vertical dielectric flank extending along the side of the top magnetic tunneling junction, and
(iv) etching the bottom magnetic tunneling junction layer to form a bottom magnetic tunneling junction.

2. The method of claim 1 wherein the step of forming the vertical dielectric flank comprises the sequential steps:
(iii.a) forming a dielectric spacer layer over the top electrode and the top magnetic tunneling junction,
(iii.b) etching the dielectric spacer layer to form the vertical dielectric flank.

3. The method of claim 2 wherein the step of forming the dielectric spacer layer over the top electrode and the top magnetic tunneling junction forms a conformal dielectric spacer layer, and the step of etching the dielectric spacer layer to form the vertical dielectric flank comprises anisotropically etching the conformal dielectric spacer layer.

4. The method of claim 1 wherein the step of forming the vertical dielectric flank comprises the sequential steps:
(iii.a) forming a spacer layer over the top electrode and the top magnetic tunneling junction,
(iii.b) patterning the spacer layer, using lithography, to form the vertical dielectric flank.

5. The method of claim 1 wherein the top magnetic tunneling junction layer further comprises a top electrode layer and patterning the top magnetic tunneling junction layer comprises patterning both layers to form the top magnetic tunneling junction and a top electrode overlying the top magnetic tunneling junction.

6. The method of claim 5 wherein the top electrode further comprises a conductive hard mask.

7. The method of claim 5 wherein patterning the top electrode layer and the top magnetic tunneling junction layer is performed in two or more distinct steps.

8. The method of claim 1 wherein the bottom magnetic tunneling junction layer further comprises a bottom electrode layer underlying the bottom magnetic tunneling junction layer and patterning the bottom magnetic tunneling junction layer comprises patterning both layers to form the bottom magnetic tunneling junction and a bottom electrode underlying the bottom magnetic tunneling junction.

9. The method of claim 8 wherein etching the bottom magnetic tunneling junction layer and the bottom electrode is performed in two or more distinct steps.

10. The method of claim 1 further comprising the additional step of (v) forming a capping layer over the top electrode, the vertical dielectric flank, the bottom magnetic tunneling junction, the bottom electrode and the substrate.

11. The method of claim 10 wherein the capping layer does not make direct contact with the top magnetic tunneling junction.

12. The method of claim 1 wherein step ii comprises etching through the tunneling barrier layer to form a tunneling barrier sandwiched between the top magnetic tunneling junction and the bottom magnetic tunneling barrier layer.

13. The method of claim 1 wherein the vertical dielectric flank extends below the bottom of the top magnetic tunneling junction to provide protection to a portion of the tunneling barrier in addition to the top magnetic tunneling junction.

14. The method of claim 1 wherein the vertical dielectric flank extends to the bottom of the tunneling barrier to provide protection to both the tunneling barrier and the top magnetic tunneling junction.

15. The method of claim 1 wherein the bottom magnetic tunneling junction is pinned and the top magnetic tunneling junction is unpinned.

16. The method of claim 1 wherein the top magnetic tunneling junction is pinned and the bottom magnetic tunneling junction is unpinned.
